(19) United States
(12) Patent Application Publication
(10) Pub. No.: US 2006/0113545 A1
(43) Pub. Date: Jun. 1, 2006

(54) Wide bandgap semiconductor layers on SOD structures

(76) Inventors: Eicke R. Weber, Piedmont, CA (US); Jerry W. Zimmer, Saratoga, CA (US)

Correspondence Address: LAWRENCE BERKELEY NATIONAL LABORATORY, ONE CYCLOTRON ROAD, MAIL STOP 90B, UNIVERSITY OF CALIFORNIA, BERKELEY, CA, 94720, US

(21) Appl. No.: 11/250,728

(22) Filed: Oct. 14, 2005

Related U.S. Application Data
(60) Provisional application No. 60/618,956, filed on Oct. 14, 2004.

(51) Int. Cl. H01L 31/0312

(52) U.S. Cl. 257/77

(57) ABSTRACT

Multi-layered structures containing GaN on SOD (silicon/diamond/silicon) substrates are described. The unique substrate/epilayer combination can provide electronic materials suitable for high-power and opto-electronic devices without commonly observed limitations due to excess heat during device operation. The resulting devices have built-in thermal heat spreading capability that result in better performance and higher reliability.

### CROSS-REFERENCE TO RELATED APPLICATIONS

This application claims priority to U.S. Patent Provisional Application 60/618,956, filed Oct. 14, 2004, which is incorporated by reference herein.

### STATEMENT OF GOVERNMENTAL SUPPORT

The invention described and claimed herein was made in part utilizing funds supplied by the U.S. Department of Energy under Contract No. DE-AC03-76SF00098, and more recently under DE-AC02-05CH11231. The government has certain rights in this invention.

### BACKGROUND OF THE INVENTION

Many electronic systems are being designed to accommodate high power transmitters that generate large thermal loads. Thus some semiconductor devices are limited in performance and end-of-life (EOL) reliability due to high device operating temperatures. High electron mobility transistor (HEMT) structures that use compound semiconductors provide high energy efficiency, but maximum performance is limited by thermal management problems during device operation. The critical reliability challenge is to minimize thermal energy near the transistor junction or channel. To improve energy transport, it is important to maximize thermal conductivity as close as possible to the active region of the transistor. Diamond provides excellent thermal conductivity, making diamond thin films ideal for dissipating heat from high power/high frequency semiconductor devices. It would be useful to use diamond films as heat spreaders in compound semiconductor devices, thus improving performance, durability, and lifetime for the devices.

### BRIEF DESCRIPTION OF THE DRAWINGS

The foregoing aspects and others will be readily appreciated by the skilled artisan from the following description of illustrative embodiments when read in conjunction with the accompanying drawings.

The widths of the layers in FIGS. 1 and 2 are not meant to convey any meaning concerning layer thicknesses.

FIG. 1 is a cross section schematic diagram showing an embodiment of the invention.

FIG. 2 is a cross section schematic diagram showing another embodiment of the invention.

FIG. 3 is a graph showing wafer bow as a function of diamond layer thickness.

FIG. 4 is a graph showing C-V measurements for an AlGaN/GaN interface in an embodiment of the invention.

FIG. 5 is a plot of carrier concentration as a function of depth, derived from the C-V data in FIG. 4.

### DETAILED DESCRIPTION

For ease of description, the disclosure herein is directed to the compound semiconductor, gallium nitride (GaN). It should be understood that the disclosure pertaining to GaN is meant to include other compound semiconductors of the form AlₓGa_{y}In_{z}AsₘPₙNₒSbₖ wherein x, y, z, m, n, o, and k are subject to the conditions that each has a value greater than or equal to zero and less than or equal to one, x+y+z=1, and m+n+o+k=1.

The growth of compound semiconductors on silicon substrates for device applications had been studied for decades. As it has not been possible to produce bulk GaN wafers with low defect density, current GaN-based device technology relies on epitaxial growth of GaN layers. However, deposition of GaN on Si is difficult due to severe wetting problems and formation of SiNₓ regions, which disrupt epitaxial growth. In some cases it is useful to deposit a buffer layer onto the Si surface before growing GaN. A buffer material layer can mitigate lattice mismatch between Si and GaN and can also provide resistance against outdiffusion of Si from the substrate. Suitable buffer materials include nitrides such as aluminum nitride (AlN) and hafnium nitride (HfN).

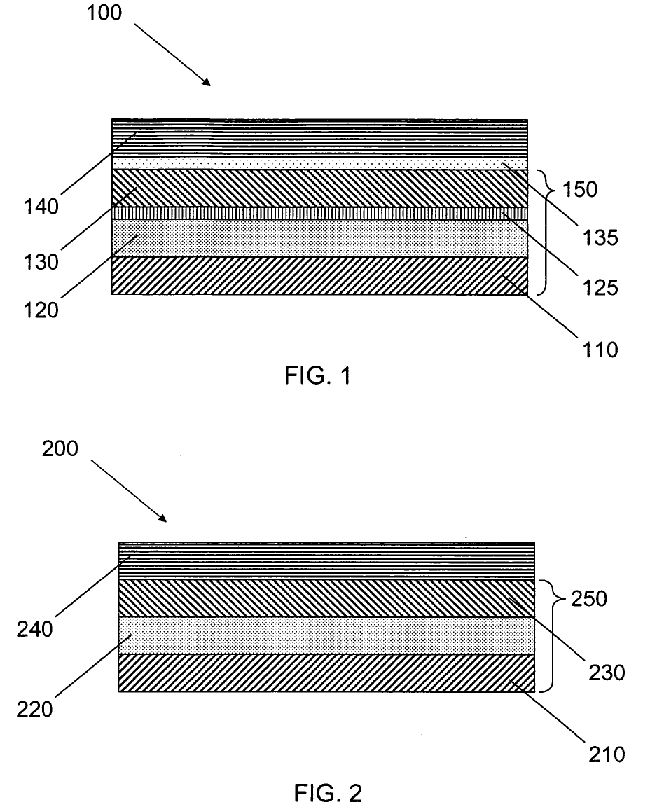

One embodiment of the present invention is shown in the cross-section schematic diagram in FIG. 1. A layered structure 100 includes a substrate 110. The substrate 110 can be silicon, polysilicon, or any other material suitable for use as a growing surface for the diamond layer 120. Above the substrate 110 is a diamond layer 120. Above the diamond layer 120 is a thin intermediate layer 125, which is discussed further below. A base layer 130, onto which an epitaxial film can be grown lies above the intermediate layer 125. The base layer 130 can be a single crystal or have a surface facing layer 104 that has a single crystal structure. In some arrangements, the base layer 130 is a silicon single crystal layer. In other arrangements, the base layer 130 can comprise, gallium arsenide, silicon carbide and/or sapphire. There is a thin buffer layer 135 disposed above the base layer 130. A GaN layer 140 lies above the buffer layer 135. In some arrangements, there are one or more additional compound semiconductor layers (not shown) above the GaN layer 140. The additional compound semiconductor layers can each have a composition different from the compound semiconductor layer 140 and can also have compositions different from one another.

A second embodiment is shown in the cross section schematic diagram in FIG. 2. A layered structure 200 includes a substrate 210. Above the substrate 210 is a diamond layer 220. The substrate 210 can be silicon or any other material suitable for use as a growing surface for the diamond layer 220. Above the diamond layer 220 is base layer 230. The base layer 230 can be a single crystal or have a surface facing layer 240 that has a single crystal structure. In some arrangements, the base layer 230 is a silicon single crystal layer. In other arrangements, the base layer 230 can comprise, gallium arsenide, silicon carbide and/or sapphire A GaN layer 240 lies above the silicon layer 230. In some arrangements, there are one or more additional compound semiconductor layers above the GaN layer 240.

The embodiment shown in FIG. 2 is simpler than the embodiment shown in FIG. 1. Other embodiments that include the elements in FIG. 2 and one or more additional elements shown in FIG. 1 but not in FIG. 2 are also within the scope of this invention. The discussion that follows refers mostly to the structure 100 shown in FIG. 1. Further information about the structure 200 shown in FIG. 2 can be gleaned from discussion of analogous elements in FIG. 1.

There are several techniques possible for growing the diamond layer 120 on the substrate 110, and each yields diamond with slightly different characteristics. Within each technique there are also ways to modify diamond characteristics to tailor the film for specific applications. The three techniques are hot filament growth, direct current (DC) plasma torch growth, and microwave plasma growth. Hot filament technology provides very uniform films and good reproducibility along with very high carbon conversion efficiency. High temperature wires generate the gas species necessary for diamond growth and can be easily scaled to areas in excess of one square meter. DC plasma torch technology provides excellent instantaneous growth rates and can be scaled to at least 300 mm diameter areas. It uses very high power density plasmas based on DC arc jets with very high gas flow rates. Initial capital costs are high even though operational costs are relatively low. Microwave plasma technology can provide very pure diamond films but is difficult to scale up beyond diameters of 2-4 inches. There are also health and safety issues with this technology. Both hot filament and DC plasma torch methods are suited for growing diamond films on silicon wafers and both are used routinely to deposit such films on wafers with diameters as large as 200 mm or larger. Diamond thin films between 0.5 to 20,000 μm in thickness can be produced on both 200-mm and 300-mm silicon wafers.

It is useful to have the diamond layer of a thickness that can conduct sufficient heat away from the active portion of devices made from the structure 100. In some arrangements, the diamond layer 120 is between about 0.5 and 50 μm. In other arrangements, the diamond layer 120 is between about 10 and 30 μm.

Diamond is typically grown in the temperature range of 600-1000° C. When diamond is grown on silicon, a substantial interfacial stress develops as the structure is cooled down to room temperature due to both differences in thermal expansion and intrinsic film stress. The interfacial stress can cause significant bow in the silicon wafer that can make subsequent processing difficult or impossible.

It is possible to alter the stress in a diamond film on silicon without significantly compromising the thermal conductivity of the diamond to any large degree. Thus the stress in the diamond/silicon wafer structure can be balanced to achieve a diamond on silicon structure of sufficient flatness to allow subsequent processing using standard wafer bonding techniques.

The diamond layer 120 may be polished to improve the quality of the surface, making it more suitable for standard wafer bonding techniques. In one embodiment, a thin intermediate layer 125 can be deposited onto the diamond layer 120. The intermediate layer 125 can be one or more of polysilicon, silicon oxides, silicon nitride, III-V semiconductors, silicon carbide, and carbon. The intermediate layer 125 may also be polished to improve the quality of the surface, making it more suitable for standard wafer bonding techniques.

Prior to depositing the interlayer 125 standard cleaning steps which are employed during device fabrication processes, as are well known in the art, can be used. The cleaning steps have no negative effects on the diamond 120 to substrate 110 interface, and the interlayer 125 grown on the diamond 120 shows no unusual characteristics. When polysilicon is deposited as the interlayer 125, temperatures as high as 1100° C. are used with no visible degradation in the structure 100.

In the embodiment shown in FIG. 2, a silicon wafer is bonded directly to the diamond layer 220. In the embodiment shown in FIG. 1, a silicon wafer is bonded to the intermediate layer 125. In both embodiments, the silicon wafer is thinned down to make the silicon on diamond (SOD) structure 150, 250. The resulting base layer 130, 230 can be polished in preparation for growing the GaN layer 140, 240.

In other embodiments of the invention, after the wafer bonding step in the process, the roles of the original substrate 110, 210 and the bonded wafer can be reversed. The original substrate 110, 210 can be thinned down and become the base layer 130, 230. The bonded wafer becomes the new substrate.

It is useful to make the base layer 130 and the intermediate layer 125 as thin as possible to maximize heat transfer and the heat spreading efficiency of the diamond layer 120 and therefore the overall power efficiency of any GaN device made from the structure 100. In some arrangements, the thickness of the base layer 130, 230 is between about 0.2 and 20 μm. In other arrangements, the thickness of the base layer is between about 0.5 and 5 μm. In some arrangements, the thickness of the intermediate layer 125 is between about 0.2 and 20 μm. In other arrangements, the thickness of the intermediate layer 125 is between about 0.5 and 5 μm

It is useful to make the SOD structure 150 as flat as possible to insure that the GaN deposition process reaches completion without physical damage to the wafer. Typically, the GaN layer 140 is deposited onto the base layer 130 at temperatures above 700° C. as the SOD structure 150 is held an electrostatic or vacuum chuck and rotated. In some arrangements the vacuum chuck can mitigate bow in the SOD structure 150 by pulling the SOD structure 150 flat.

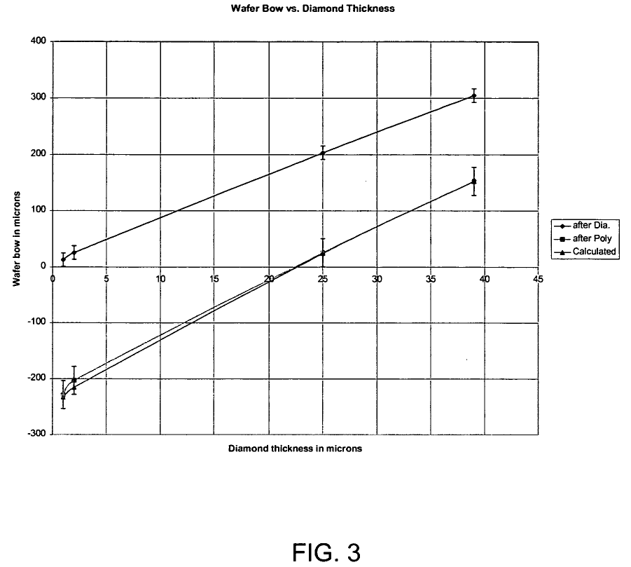

Measurements of wafer bow before and after polysilicon (intermediate layer 125) deposition show that the polysilicon film adds a net tensile stress component to the top surface which compensates the compressive stress generated by the diamond layer 120. FIG. 3 shows wafer bow as a function of diamond thickness before and after 25 microns of polysilicon deposition. The third line plotted on the graph is a calculated wafer bow based on a Young's modulus of 500 GPa for the diamond film and 190 GPa for the silicon. Using the ratio of the two, the effective thickness of the wafer if it were all silicon can be calculated and this can be used to calculate the bow. The 500 GPa number is somewhat low for diamond but it allows the best fit for the existing data and may not be unreasonable for a thin film. The net calculated stress level for the polysilicon film is 1.7 KPa and represents both intrinsic stress in the film as well as the stress generated by the thermal expansion mismatch between the polysilicon and the diamond layer. Approximately 80% of the polysilicon layer is removed during the wafer bonding process but stress from the thermal expansion mismatch remains as well as a substantial portion of the film stress.

GaN layers are then grown onto either layer 135 or layer 230 using standard processes for growing compound semiconductor device layers onto base layers suitable for epitaxial growth.

Finished layered structures 100, 200 on substrates with diameters from about 100 to 300 mm have bow measurements of no more than about 25 μm concave shape and no more that about 300 μm convex shape as viewed facing the compound semiconductor layer 140, 240, respectively.

### EXAMPLE

Growth of a device quality AlGaN/GaN HEMT structure on 100 mm silicon-on-diamond (SOD) substrates was performed. Growth was done on a initial SOD wafer with thin diamond and relatively thick silicon on top of the diamond. The 100 mm SOD substrate consisted of a base wafer (3-6 ohm-cm <111> p type silicon), a diamond layer (˜3 micron), a polysilicon layer (˜23 microns) and a top silicon layer (˜15 microns of <111> float zone (FZ) silicon [>10 kohm-cm]). Thickness values are based on interpretation of a focused ion beam (FIB) cross section of the finished wafer. The vast majority of the SOD substrate had the appearance of a typical epi-ready FZ Si wafer routinely used for growth of GaN on Si. Microscope inspection of the interior of the wafer before growth revealed a featureless surface.

The structure consisted of a (Al,Ga)N transition layer, a GaN buffer layer, a 175 Å Al0.26Ga0.74N device layer, and a ˜20 Å GaN cap layer. Growth was carried out in a vertical, cold wall, rotating disk reactor at ˜1020° C. The column III precursors used were trimethylaluminum (TMA) and trimethylgallium (TMG); ammonia (NH₃, 9.5 grade) was used as the column V precursor and Pd-diffused H₂ was used as the carrier gas. The wafer was loaded into the reactor as delivered; no cleaning or etching was performed prior to loading. After growth, the vast majority of the wafer was specular. Under microscope inspection, the surface morphology of the AlGaN/GaN structure was typical over the majority of the wafer.

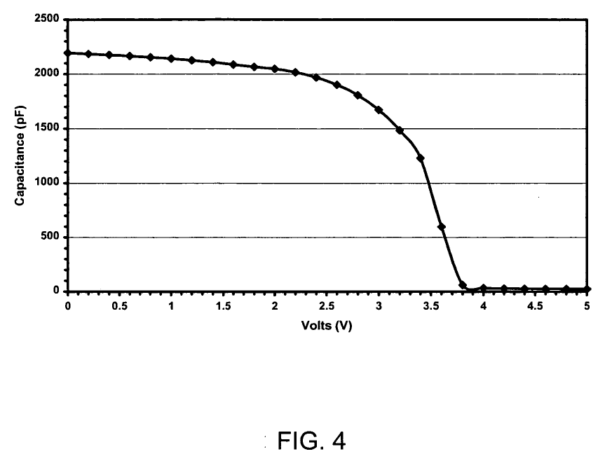

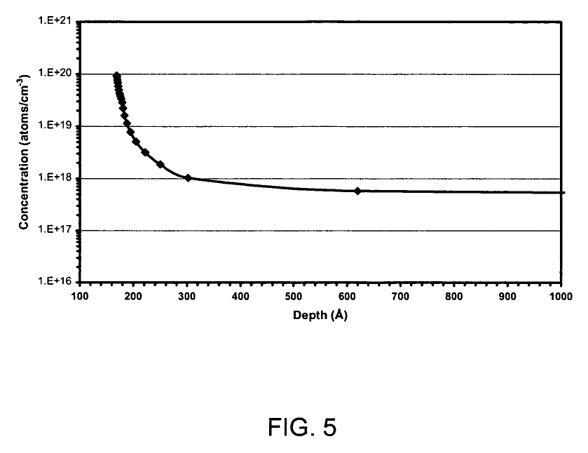

Capacitance-voltage (C-V) measurement was performed using a mercury probe technique to confirm the presence of an electron channel at the AlGaN/GaN interface. The raw CV data, shown in FIG. 4, exhibits good pinch off behavior with a pinch-off voltage slightly less than four volts. A plot of carrier concentration vs. depth, derived from the C-V data, is shown in FIG. 5. The highly localized peak electron concentration obtained here is ˜1×10²⁰ cm³, with an estimated device layer thickness of 169 Å. These results demonstrate that device quality epilayers can be grown on a SOD structure.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. A multi-layered article, comprising, in order:
a substrate;
a thermally conductive diamond layer;
a base layer suitable for epitaxial growth; and
a first compound semiconductor layer.

2. The article of claim 1 wherein the base layer comprises a single crystal structure.

3. The article of claim 2 wherein the base layer is selected from the group consisting of silicon, gallium arsenide, silicon carbide and sapphire.

4. The article of claim 1 wherein the base layer comprises single crystal silicon.

5. The article of claim 1 wherein the first compound semiconductor layer comprises AlₓGa_{y}In_{z}AsₘPₙNₒSbₖ wherein x, y, z, m, n, o, and k each has a value greater than or equal to zero and less than or equal to one and x+y+z=1, and m+n+o+k=1.

6. The article of claim 5 wherein the first compound semiconductor layer comprises GaN.

7. The article of claim 1 further comprising a second compound semiconductor layer comprising AlₓGa_{y}In_{z}AsₘPₙNₒSbₖ wherein x, y, z, m, n, o, and k each has a value greater than or equal to zero and less than or equal to one and x+y+z=1, and m+n+o+k=1, wherein the second compound semiconductor layer has a composition different from the first compound semiconductor layer.

8. The article of claim 1 further comprising a buffer layer disposed between the base layer and the first compound semiconductor layer.

9. The article of claim 8 wherein the buffer layer is selected from the group consisting of HfN, and AlN.

10. The article of claim 1 further comprising an intermediate layer disposed between the diamond layer and the base layer.

11. The article of claim 10 wherein the intermediate layer is selected from the group consisting of polysilicon, silicon oxides, silicon nitride, silicon carbide, carbon, III-V semiconductors or combinations thereof.

12. The article of claim 1 wherein the diamond layer acts as a thermal heat spreader for the compound semiconductor layer and has a thermal conductivity between about 400 and 2200 W/m/K.

13. The article of claim 1 wherein the article has a bow measurement of no more than about 25 μm concave shape and no more that 300 μm convex shape as viewed facing the compound semiconductor layer.

14. A layered structure, comprising, in order:
a silicon substrate;
a thermally conductive diamond layer;
a single crystal silicon layer; and
an epitaxial GaN layer;

15. The structure of claim 14 wherein the structure has a bow measurement of no more than about 25 μm concave shape and no more that 300 μm convex shape as viewed facing the Ga N layer.

16. A layered structure, comprising, in order:
a silicon substrate;
a thermally conductive diamond layer;
a polysilicon layer;
a single crystal silicon layer;
a nitride buffer layer; and
an epitaxial compound semiconductor layer.

17. The structure of claim 16 wherein the nitride buffer layer is selected from the group consisting of HfN and AlN.
